(19) United States
(12) Patent Application Publication
(10) Pub. No.: US 2012/0009728 A1
(43) Pub. Date: Jan. 12, 2012

(54) Apparatus and Method for Manufacturing CIGS Solar Cells

(75) Inventor: Yan-Way LI, TAICHUNG COUNTY (TW)

(73) Assignee: GCSOL TECH CO., LTD., Taichung County (TW)

(21) Appl. No.: 12/889,409

(22) Filed: Sep. 24, 2010

(30) Foreign Application Priority Data
Jul. 8, 2010 (TW) 99122507

(51) Int. Cl. H01L 31/18

(52) U.S. Cl. 438/89; 118/719; 438/95; 257/E31.001

(57) ABSTRACT

An apparatus and a method for manufacturing a CIGS solar cell are disclosed. The apparatus includes a buffer chamber, a first chamber, a second chamber and a mechanical device. The first chamber and the second chamber are located adjacent to the buffer chamber respectively. The mechanical device moves a substrate among the buffer chamber, the first chamber and the second chamber. The first chamber includes a deposition device for depositing a back electrode layer onto the substrate. The second chamber includes heat treatment device and for becoming a thin-film layer onto the back electrode layer.

### RELATED APPLICATIONS

The application claims priority to Taiwan Application Serial Number 99122507, filed Jul. 8, 2010, which is herein incorporated by reference.

### BACKGROUND

1. Technical Field

The present disclosure relates to CIGS (Copper Indium Gallium Selenide) solar cells. More particularly, the present disclosure relates to an apparatus and a method for manufacturing CIGS solar cells.

2. Description of Related Art

As the phenomenon of the global warming and energy crisis is growing, many people devote to energy development, especially, on solar energy. Silicon (Si) is the most widely used material for solar cell. But, Silicon (Si) costs high price. Therefore, many materials are discovered for decreasing the cost and improving the efficiency of the photoelectric conversion, such as CIGS(Copper Indium Gallium Selenide) solar cells.

Some prior art method described a two-stage process to produces a GIGS or CIGSS (Copper Indium Gallium Sulfur-Selenide) film on a substrate for semiconductor applications. The two-stage process, wherein selenium and sulfur can be added to the absorber crystal matrix by heating copper indium alloys with H₂Se gas or Se and S vapors, but H₂Se gas has several disadvantages with highly toxic, low selenium utilization, and poor adhesion to molybdenum coated substrates that as undesirable chemical for industrial scale manufacturing.

A recently attempt to improve manufacturing of solar cells with a roll-to-roll technique. The roll-to-roll machine, which consists essentially of a series of individual processing chambers each adapted to the preparation of a solar cell. Several of the layers are formed by physical vapor deposition method with the desired materials in vacuum chambers. For preparing the absorber of a solar cell, however, the deposited vapor is volatilized by several materials melted in crucibles to evaporate and deposit on a thin foil. The deposition apparatus does not have a device to activate the selenium vapor to enhance the quality of the absorber.

In terms of produced CIGS by co-evaporation method, the melting point for CIGS includes four different elements require different temperature control to heating and evaporation crucible in a vacuum under the substrate evenly mixed to from thin films. Wants to use a single crucible to melt four kinds of metal material simultaneously, its composition coated film will be difficult to control, because the melting point of gallium, indium and copper are quite different.

Vertical joint above, the deposition system can be improved for CIGS production, but the high reactivity of hydrogen selenide (H₂Se) or hydrogen sulfide (H₂S) of the highly toxic gas, or personal safety of the environment both has its hazards exist; the other hand, the atmosphere in selenium or sulfur vapor shows in large molecular aggregates in the traditional use of the resulting CIGS or CIGSS absorbing layer still has a very high defect concentration, resulting in instability of the quality of presentation.

### SUMMARY

An apparatus for manufacturing a CIGS solar cell includes a buffer chamber, a first chamber, a second chamber and a mechanical device. The first chamber and the second chamber are located adjacent to the buffer chamber. The mechanical device moves the substrate among the buffer chamber, the first chamber and the second chamber. The first chamber includes a deposition device therein. The second chamber includes heat treatment device therein. The heat treatment device includes a base, a crucible, a first heat device, a pipe and a cover member. The base sets a substrate. The crucible is located outside of the second chamber for containing a fusion material. The first heat device heats the fusion material. One end of the pipe is connected to the crucible, and the other end of the pipe is within the second chamber. The cover member faces the end of the pipe which is located in the second chamber and has at least one adjustable hole.

A method for manufacturing a GIGS solar cell includes the steps

(a) moving a substrate into a first chamber by a mechanical device and depositing a back electrode layer onto the substrate, wherein the back electrode layer includes Molybdenum;

(b) moving the substrate into a second chamber by the mechanical device and then heating and activating a fusion material to a vapor, the vapor passing through a plurality of adjustable holes of a cover member and becoming a thin-film layer;

(c) moving the substrate into the first chamber by the mechanical device and depositing a first precursor layer and a second precursor layer; and

(d) moving the substrate into the second chamber by the mechanical device and forming a light absorption layer.

### BRIEF DESCRIPTION OF THE DRAWINGS

FIG. 1 is a diagram of an apparatus for manufacturing a CIGS solar cell according to one embodiment;

FIG. 2 is a diagram of the second chamber of FIG. 1;

FIG. 3A is a diagram of the cover member of FIG. 1;

FIG. 3B is a diagram of the cover member of an apparatus for manufacturing a CIGS solar cell according to another embodiment;

FIG. 4 is a diagram of the base of FIG. 1;

FIG. 5 is a flowchart of a method for manufacturing the CIGS solar cell according to further another embodiment; and

FIG. 6 is a cross-sectional picture analyzed by scanning electron microscopy of the CIGS solar cell made from the method of FIG. 5.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically depicted in order to simplify the drawings.

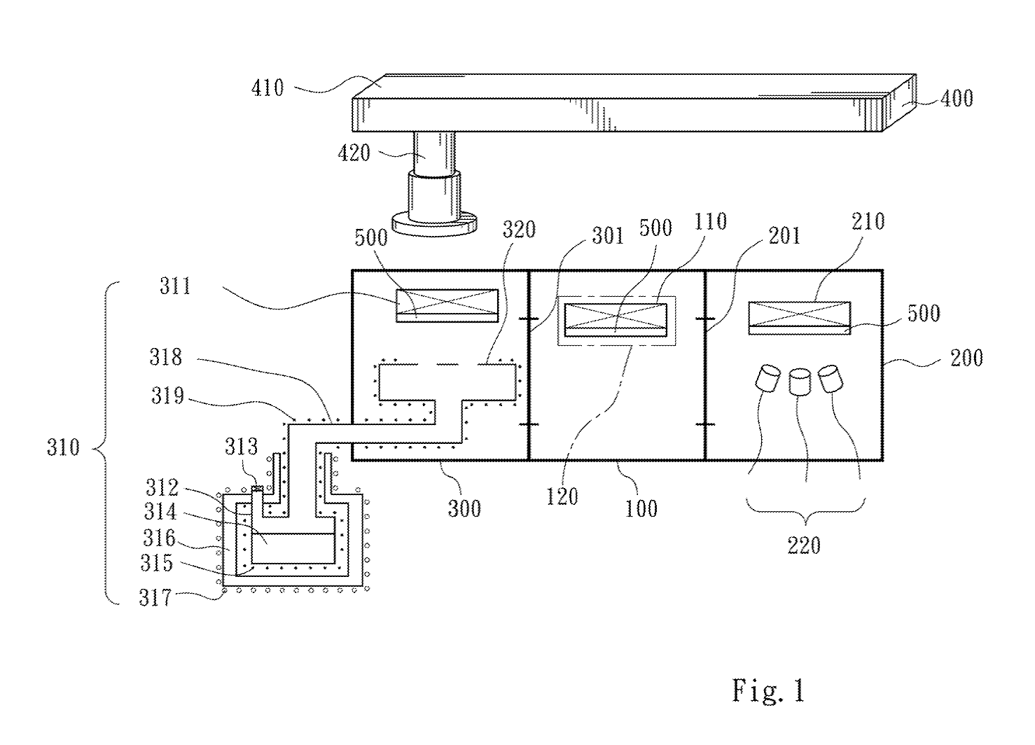

FIG. 1 is a diagram of an apparatus for manufacturing a GIGS solar cell according to one embodiment. The apparatus includes a buffer chamber 100, a first chamber 200, a second chamber 300 and a mechanical device 400. The first chamber 200 and the second chamber 300 are located adjacent to the buffer chamber 100. The mechanical device 400 moves substrates 500 among the buffer chamber 100, the first chamber 200 and the second chamber 300. The first chamber 200 includes a deposition device 220 therein. The second chamber 300 includes a heat treatment device 310 therein. The heat treatment device 310 includes a base 311, a crucible 312, a first heat device 315, a pipe 318 and a cover member 320. The base 311 sets a substrate 500. The crucible 312 is located outside of the second chamber 300 for containing a in fusion material 314. The first heat device 315 heats the fusion material 314. One end of the pipe 318 is connected to the crucible 312, and the other end of the pipe 318 is within the second chamber 300. The cover member 320 covers the end of the pipe 318 which is located in the second chamber 300 and has at least one adjustable hole.

In detail, the mechanical device 400 includes a rail 410 and a robot arm 420. The robot arm 420 can take the substrate 500, move the substrate 500 along the rail 410, and then put the substrate 500 into the buffer chamber 100, the first chamber 200 or the second chamber 300.

The buffer chamber 100 is a vacuum and includes a base 110 and a temperature controller 120 therein. The base 110 can support the substrate 500. The substrate 500 is moved into the buffer chamber 100 by the mechanical device 400, and the temperature controller 120 can heat or cool the substrate 500 to achieve a determined temperature. For example, the temperature controller 120 for heating can be a heating coil and the temperature controller 120 for cooling can be a cooling pipe.

The first chamber 200 is a vacuum. A vacuum valve 201 is connected to the junction of the buffer chamber 100 and the first chamber 200. The first chamber 200 includes a base 210 and a deposition device 220. The mechanical device 400 moves the substrate 500 into the first chamber 200, and the base 210 supports the substrate 500. The deposition device 220 can contain at least one deposition material. In FIG. 1, the deposition device 220 contains three deposition materials, that is, Molybdenum (Mo), Indium (In) and Copper gallium alloy. The deposition device 200 can perform physical vapor deposition (PVD), atomic layer deposition (ALD), chemical vapor deposition (CVD), or metal-organic chemical vapor deposition (MOCVD).

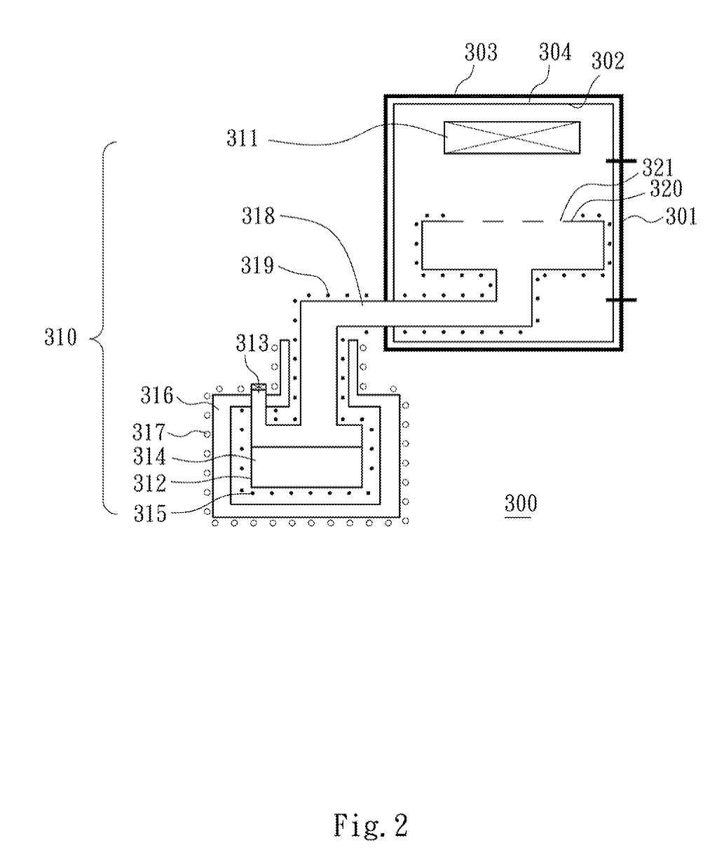

FIG. 2 is a diagram of the second chamber 300 of FIG. 1. The second chamber 300 is a vacuum, too. A vacuum valve 301 is connected to the junction of the buffer chamber 100 and the second chamber 300. The second chamber 300 has an inside wall 302 and an outside wall 303. The space 304 between the inside wall 302 of the second chamber 300 and the outside wall 303 of the second chamber 300 is a vacuum. Therefore, the second chamber 300 can avoid the interference from the environment in use.

The crucible 312 of the heat treatment device 310 includes a feeding hole 313 for filling or replenishing the fusion material 314. The fusion material 314 is selenium (Se). Further, the fusion material 314 can also be sulfur (S). The first heat device 315 of the heat treatment device 310 is a heating coil. The heating coil surrounds the crucible 312 for heating the selenium (Se) in the crucible 312. The selenium can be maintained at 260° C.-380° C. and continually vaporized to be the selenium (Se) vapor. The selenium (Se) vapor passes through the pipe 318 and is deposited onto the substrate 500.

The heat treatment device 310 includes a second heat device 319. The second heat device 319 is located on the outside of the pipe 318. The second heat device 319 is a heating coil. The second heat device 319 provides the heat at 500° C.-700° C. When the selenium (Se) vapor passes through the pipe 318, the second heat device 319 can provide the secondary heat for heating the clusters of selenium molecule. The clusters of the selenium molecule will collide to each other and crack into the smaller clusters of selenium molecule. The deposition of the smaller clusters of selenium molecule onto the substrate 500 will be even.

The heat treatment device 310 further includes a heat insulated component 316 and a cooling pipe 317. The heat insulated component 316 surrounds the outside of crucible 312 and the end of the pipe 318 close to the crucible 312. The cooling pipe 317 surrounds the heat insulated component 316. The cooling pipe 317 can let the cold water pass through, so that the cooling pipe 317 isolates the crucible 312 and the pipe 318 from the environment. Therefore, the high temperature of the crucible 312 and the first heat device 315 will not affect the other devices nearby.

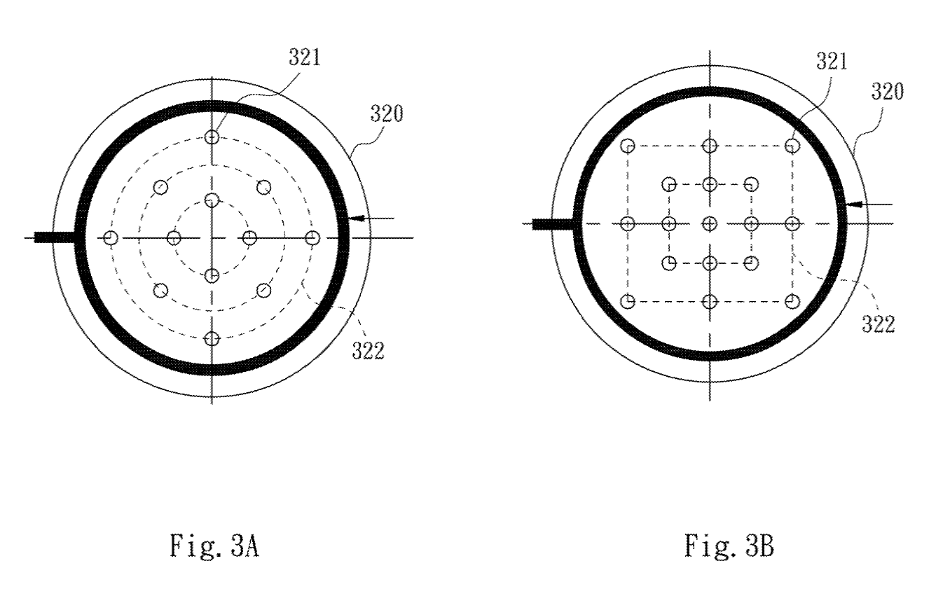

FIG. 3A is a diagram of the cover member 320 of FIG. 1, and FIG. 3B is a diagram of the cover member of an apparatus for manufacturing a CIGS solar cell according to another embodiment. The cover member 320 covers the end of the pipe 318 which is located in the second chamber 300. The cover member 320 has a plurality of adjustable holes 321. In other words, the adjustable holes 321 can be opened or closed to control the vapor flux on or off.

Further, the plurality of the adjustable holes 321 are arrayed set on the cover member 320 in a matrix-array arrangement. In other words, the adjustable holes 321 are arranged on the cover member 320 evenly. Therefore, the selenium vapor can pass through the adjustable holes 321 and is deposited onto the substrate 500 evenly.

Furthermore, the cover member 320 further includes a heating coil 322 (in FIG. 3A and FIG. 3B). The selenium vapor can be re-heated by the heating coil 322 of the cover member 320 when it passes through the adjustable holes 321 of the cover member 320.

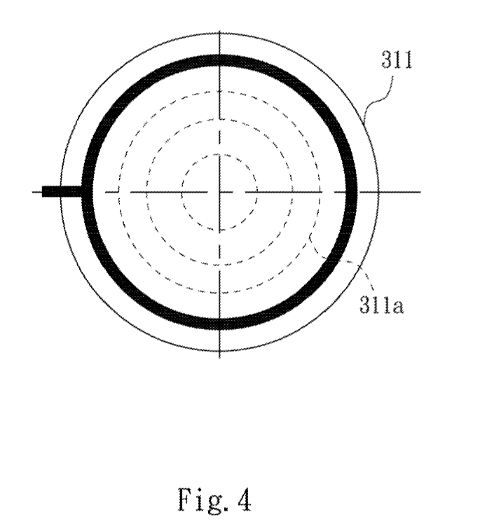

FIG. 4 is a diagram of the base 311 of FIG. 1. Therefore, the Selenium (Se) vapor can be deposited onto the substrate 500 evenly. The base 311 of the heat treatment device 310 is rotatable and for loading the substrate. The base 311 includes a heat device 311a which could be a bank of heating lamps or a resistance coils for heating the substrate 500. Furthermore, the heat radiating from the heating coil 322 of the cover member 320 and the heat irradiating from the heating device 311a can interact with each other and become a heating field. The heating field envelops the rotating substrate completely and the heat insulated effect from the space 304 of the second chamber 300 can control the temperature uniformity of the center and edge of large area substrate.

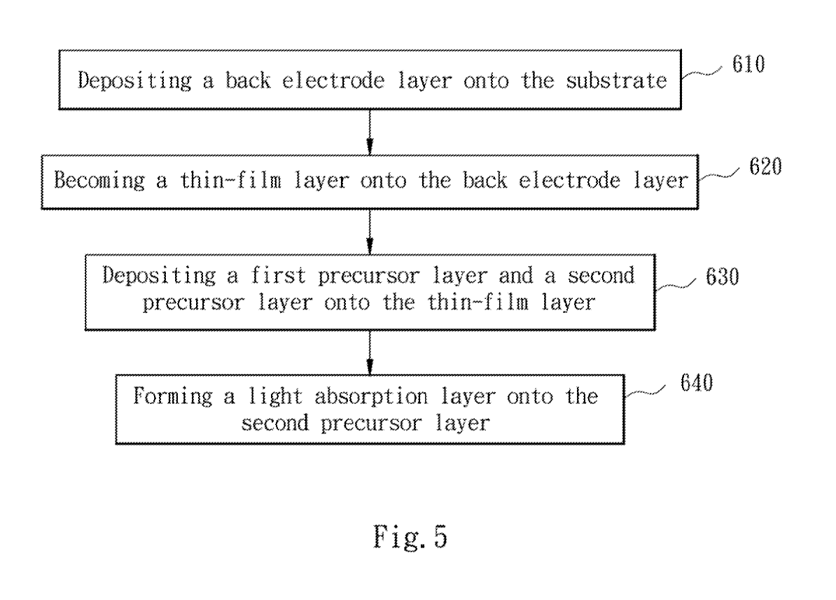

FIG. 5 is a flowchart of a method for manufacturing the GIGS solar cell according to further another embodiment. The method includes the steps:

Step 610: Moving a substrate into a first chamber by a mechanical device and depositing a back electrode layer onto the substrate, wherein the back electrode layer comprises Molybdenum;

Step 620: Moving the substrate into a second chamber by the mechanical device and then heating a fusion material to a vapor, the vapor passing through a plurality of adjustable holes of a cover member and becoming a thin-film layer onto the back electrode layer, wherein the fusion material is selenium;

Step 630: Moving the substrate into the first chamber by the mechanical device and depositing a first precursor layer and a second precursor layer onto the thin-film layer, wherein the first precursor layer is an Indium thin-film layer and the second precursor layer is a copper gallium alloy thin-film; and

Step 640: Moving the substrate into the second chamber by the mechanical device and forming a light absorption layer on the substrate.

In step 610, the way deposited the back electrode layer is ALD, CVD, MOCVD or PVD.

In step 620, the adjustable holes are arrayed set on the cover member. Therefore, the fusion material can be deposited onto the substrate 500 evenly. Further, the fusion material can be activated by an electron beam device, an ion beam device, a plasma resonance device or a pyrolysis device.

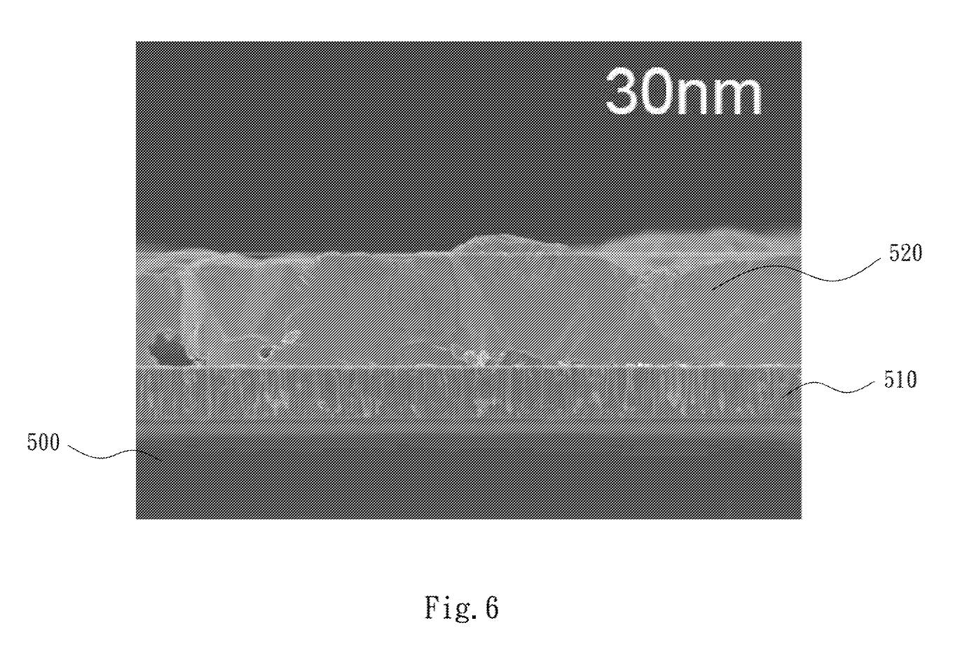

FIG. 6 is a cross-sectional picture analyzed by scanning electron microscopy of the GIGS solar cell made from the method of FIG. 5. In FIG. 6, a 30 nm of the thin-film layer is deposited between the back electrode layer 510 and the first precursor layer 520 by using the methods of FIG. 5. Therefore, it has a smooth interface between the back electrode layer 510 and the first precursor layer 520 after the heat treatment.

What is claimed is:

1. An apparatus for manufacturing a GIGS solar cell, the apparatus comprising:
a buffer chamber;
a first chamber located adjacent to the buffer chamber and comprising:
a deposition device therein;
a second chamber located adjacent to the buffer chamber and comprising:
a heat treatment device comprising:
a base for setting a substrate;
a crucible located outside of the second chamber for containing a fusion material;
a first heat device for heating the fusion material;
a pipe, one end of the pipe connected to the crucible, the other end of the pipe within the second chamber; and
a cover member facing the end of the pipe within the second chamber and having at least one adjustable hole; and
a mechanical device for moving the substrate among the buffer chamber, the first chamber and the second chamber.

2. The apparatus for manufacturing the GIGS solar cell of claim 1, further comprising:
a second heat device located on the outside of the pipe.

3. The apparatus for manufacturing the GIGS solar cell of claim 2, wherein the second heat device is a heating coil.

4. The apparatus for manufacturing the GIGS solar cell of claim 1, wherein the space between the inside wall of the second chamber and the outside wall of the second chamber is a vacuum.

5. The apparatus for manufacturing the CIGS solar cell of claim 1, wherein the buffer chamber, the first chamber and the second chamber are vacuums.

6. The apparatus for manufacturing the CIGS solar cell of claim 1, further comprising:
a vacuum valve connected to the junction of both of the buffer chamber, the first chamber and the second chamber.

7. The apparatus for manufacturing the CIGS solar cell of claim 1, wherein the base is rotatable.

8. The apparatus for manufacturing the GIGS solar cell of claim 1, wherein the base comprises a heat device.

9. The apparatus for manufacturing the CIGS solar cell of claim 1, wherein the crucible comprises a feeding hole.

10. The apparatus for manufacturing the CIGS solar cell of claim 1, wherein the fusion material is selenium or sulfur.

11. The apparatus for manufacturing the GIGS solar cell of claim 1, wherein the first heat device is a heating coil.

12. The apparatus for manufacturing the CIGS solar cell of claim 1, wherein the adjustable holes are arrayed set on the cover member.

13. The apparatus for manufacturing the CIGS solar cell of claim 1, wherein the cover member comprises a heating coil.

14. The apparatus for manufacturing the GIGS solar cell of claim 1, wherein the heat treatment device comprises a heat insulated component, which surrounds the outside of the crucible and the end of the pipe close to the crucible.

15. The apparatus for manufacturing the CIGS solar cell of claim 14, wherein the heat treatment device further comprises a cooling pipe and the cooling pipe surrounds the heat insulated component.

16. The apparatus for manufacturing the GIGS solar cell of claim 1, wherein the buffer chamber comprises a temperature controller.

17. A method for manufacturing a CIGS solar cell, the method comprising:
(a) moving a substrate into a first chamber by a mechanical device and depositing a back electrode layer onto the substrate, wherein the back electrode layer comprises Molybdenum;
(b) moving the substrate into a second chamber by the mechanical device and then heating and activating a fusion material to a vapor, the vapor passing through a plurality of adjustable holes of a cover member and becoming a thin-film layer;
(c) moving the substrate into the first chamber by the mechanical device and depositing a first precursor layer and a second precursor layer; and
(d) moving the substrate into the second chamber by the mechanical device and forming a light absorption layer.

18. The method for manufacturing the GIGS solar cell of claim 17, wherein the way deposited the back electrode layer is atomic layer deposition, chemical vapor deposition, metal-organic chemical vapor deposition or physical vapor deposition.

19. The method for manufacturing the GIGS solar cell of claim 17, wherein the fusion material is activated by an electron beam device, an ion beam device, a plasma resonance device or a pyrolysis device.

20. The method for manufacturing the CIGS solar cell of claim 17, wherein the fusion material is Selenium (Se) or Sulfur (S).

21. The method for manufacturing the CIGS solar cell of claim 17, wherein the adjustable holes are arrayed set on the cover member.
